(19) United States
(12) Patent Application Publication
(10) Pub. No.: US 2021/0167155 A1
(43) Pub. Date: Jun. 3, 2021

(54) THIN-FILM TRANSISTOR, MANUFACTURING METHOD THEREOF, ARRAY SUBSTRATE AND DISPLAY DEVICE

(71) Applicant: BOE TECHNOLOGY GROUP CO., LTD., Beijing (CN)

(72) Inventors: Pan XU, Beijing (CN); Yongqian LI, Beijing (CN); Zhidong YUAN, Beijing (CN); Zhenfei CAI, Beijing (CN); Can YUAN, Beijing (CN); Meng LI, Beijing (CN)

(73) Assignee: BOE TECHNOLOGY GROUP CO., LTD., Beijing (CN)

(21) Appl. No.: 16/063,774

(22) PCT Filed: Dec. 18, 2017
(86) PCT No.: PCT/CN2017/116903

§ 371 Date: Jun. 19, 2018

(30) Foreign Application Priority Data
Apr. 6, 2017 (CN) 201710221302.5

(51) Int. Cl. H01L 27/32; H01L 29/786; H01L 51/52; H01L 29/40

(52) U.S. Cl. CPC H01L 27/3272; H01L 29/401; H01L 51/5221; H01L 29/7869

(57) ABSTRACT

A thin-film transistor includes a substrate, and a light-shielding layer and an active layer sequentially over the substrate. The light-shielding layer has an accommodating space having a bottom wall and a side wall on an upper surface thereof. An orthographic projection of the active layer on the substrate is contained within an orthographic projection of the accommodating space of the light-shielding layer on the substrate. An upper side of the side wall of the accommodating space of the light-shielding layer has a larger distance to the substrate than a bottom surface, and optionally has an equal or larger distance to the substrate than a top surface, of the active layer. The light-shielding layer can comprise a gate electrode. As such, lights from an underneath and from a lateral side of the thin-film transistor that otherwise reach the active layer can be partially or completely blocked.

### CROSS-REFERENCE TO RELATED APPLICATION

The present application claims priority to Chinese Patent Application No. 201710221302.5 filed on Apr. 6, 2017, the disclosure of which is hereby incorporated by reference in its entirety.

### TECHNICAL FIELD

The present disclosure relates generally to the field of semi-conductor technologies, and more specifically to a thin-film transistor, a manufacturing method thereof, an array substrate that includes the thin-film transistor, and a display device comprising the array substrate.

### BACKGROUND

With the development of flat panel display industry, the requirements for display devices have become higher and higher, and the requirements for the mobility rate of thin-film transistor in display panels of the display devices have also become higher.

At present time, in the current display panel industry and market, a thin-film transistor that has been commonly utilized in a conventional display panel typically includes an amorphous silicon thin-film transistor. In other words, in the amorphous silicon thin-film transistor, an active layer of the thin-film transistor typically has a composition of amorphous silicon.

The mobility rate of carriers in an amorphous silicon thin-film transistor is relatively low, and the mobility rate of electrons is around 0.1-1 cm²V⁻¹s⁻¹, which thus fail to meet the requirements for the development in the display industry. As such, low-temperature polysilicon (LTPS) and oxide thin-film transistor have been developed and has become more and more employed in the display panels.

### SUMMARY

The present disclosure provides a thin-film transistor and a manufacturing method thereof, an array substrate and a display device.

In a first aspect, the present disclosure provides a thin-film transistor. The thin-film transistor includes a substrate, a light-shielding layer, and an active layer. The light-shielding layer is disposed over the substrate, and the active layer is disposed over the light-shielding layer. The light-shielding layer is provided with an accommodating space having a bottom wall and a side wall on an upper surface of the light-shielding layer.

The active layer is arranged such that an orthographic projection of the active layer on the substrate is contained within an orthographic projection of the accommodating space of the light-shielding layer on the substrate. It is further configured that a bottom surface of the active layer has a shorter distance to the substrate than an upper side of the side wall of the accommodating space of the light-shielding layer to the substrate.

Optionally, it can be further configured that a top surface of the active layer has an equal, or shorter distance to the substrate than the upper side of the side wall of the accommodating space of the light-shielding layer to the substrate.

According to some embodiments of the thin-film transistor, the light-shielding layer comprises a gate electrode. As such, the gate electrode can be provided with a first groove on an upper surface thereof, and the first groove substantially forms the accommodating space of the light-shielding layer.

Optionally, the substrate can be provided with a second groove on an upper surface thereof, and it can be configured such that the first groove of the gate electrode that is disposed over the substrate is conformal with the second groove of the substrate.

According to some embodiments, the thin-film transistor further includes at least one intermediate layer between the substrate and the gate electrode. Each of the at least one intermediate layer is provided with a third groove on an upper surface thereof, configured such that the third groove is conformal with the first groove of the gate electrode.

In any one of the embodiments of the thin-film transistor as mentioned above, the active layer can have a composition of an oxide semiconductor material.

In a second aspect, the disclosure further provides an array substrate. The array substrate includes a thin-film transistor according to any one of the embodiments as described above.

According to some embodiments of the array substrate, the array substrate further includes a light filtering layer. The light filtering layer is disposed over the active layer of the thin-film transistor. It is configured such that an orthographic projection of the light filtering layer on the substrate covers an orthographic projection of the active layer on the substrate, and that the light filtering layer is configured to reduce or block lights from above the active layer to reach the active layer.

Herein the light filtering layer in the thin-film transistor can have a composition of a light-blocking material, which is configured to substantially block the lights from above the active layer to reach the active layer.

According to some embodiments of the array substrate, the light filtering layer in the thin-film transistor can have a composition configured to absorb a relatively short-wavelength light yet still allow a relatively long-wavelength light to pass therethrough. For example, the light filtering layer in the thin-film transistor can be a red color filter layer.

The array substrate may further include a light-emitting assembly, which is selected from OLED, QLED, or micro LED.

In some embodiments of the array substrate, the light-emitting assembly is an OLED light-emitting assembly. The OLED light-emitting assembly comprises a light-emitting layer and a cathode layer. The light-emitting layer is disposed over the light filtering layer as mentioned above, and the cathode layer is disposed over the light-emitting layer.

According to some preferred embodiments, the cathode layer is configured to be reflective on a surface thereof facing the light-emitting layer.

In a third aspect, the present disclosure further provides a method for manufacturing a thin-film transistor. The manufacturing method comprises the following steps:

providing a substrate;

forming a light-shielding layer over the substrate such that an accommodating space having a bottom wall and a side wall is formed on an upper surface thereof; and

forming an active layer over the light-shielding layer such that an orthographic projection thereof on the substrate is within an orthographic projection of the accommodating space of the light-shielding layer on the substrate, and a bottom surface thereof has a shorter distance to the substrate than an upper side of the side wall of the accommodating space of the light-shielding layer to the substrate.

According to some embodiments of the method, in the step of forming an active layer over the light-shielding layer, the active layer is further arranged such that a top surface thereof has an equal, or shorter distance to the substrate than the upper side of the side wall of the accommodating space of the light-shielding layer to the substrate.

According to some embodiments of the method, the light-shielding layer can include a gate electrode of the thin-film transistor, and the accommodating space can be directly formed in the gate electrode.

As such, the step of forming a light-shielding layer over the substrate in the manufacturing method can comprise a sub-step of:

forming a gate electrode over the substrate such that a first groove is formed on an upper surface thereof to substantially form the accommodating space of the light-shielding layer.

Herein the sub-step of forming a gate electrode over the substrate can comprise the following:

forming a gate electrode thin film over the substrate;

forming a photoresist layer over the gate electrode thin film;

treating the photoresist layer to obtain a processed photoresist layer to thereby define the pattern of the gate electrode; and

etching the gate electrode thin film utilizing the processed photoresist layer as a mask to thereby form the gate electrode.

Specifically, the treating the photoresist layer to obtain a processed photoresist layer can comprise:

using a mask plate to treat the photoresist layer, wherein a translucent region is arranged in the mask plate to correspond to a region of the groove.

Herein, the mask plate can be a half-tone mask plate or a gray-tone mask plate.

According to some embodiments of the method, the step of providing a substrate comprises:

providing the substrate; and

forming a second groove on a top surface of the substrate;

Furthermore, the step of forming a gate electrode over the substrate comprises:

forming a gate electrode thin film having a thickness thereof smaller than a depth of the second groove; and

performing a patterning process over the gate electrode thin film to thereby form the gate electrode.

Other embodiments may become apparent in view of the following descriptions and the attached drawings.

### BRIEF DESCRIPTION OF THE DRAWINGS

To more clearly illustrate some of the embodiments, the following is a brief description of the drawings. The drawings in the following descriptions are only illustrative of some embodiments. For those of ordinary skill in the art, other drawings of other embodiments can become apparent based on these drawings.

FIG. 1 is a structural diagram of a thin-film transistor according to some embodiment of the present disclosure;

FIG. 2 is a structural diagram of a thin-film transistor according to some other embodiment of the present disclosure;

FIG. 3 is a structural diagram of a thin-film transistor according to yet another embodiment of the present disclosure;

FIG. 4 is a structural diagram of an array substrate according to some embodiments of the present disclosure;

FIG. 5 is a flow chart illustrating a manufacturing method of a thin-film transistor according to some embodiments of the present disclosure;

FIG. 6 is a flow chart illustrating the sub-steps of forming a pattern of a gate electrode through a one-time patterning process over the gate electrode thin film according to some embodiments of the disclosure;

FIG. 7 is a flow chart illustrating the sub-steps of forming a pattern of a gate electrode through a one-time patterning process over the gate electrode thin film according to some embodiments of the disclosure;

FIGS. 8A, 8B, 8C and 8D are diagrams of the structures formed after executing each sub-step during the process of forming the pattern of the gate electrode in the manufacturing method according to some embodiments of the present disclosure;

FIG. 9 is a flow chart illustrating the sub-steps of forming a pattern of a gate electrode through a one-time patterning process over the gate electrode thin film according to some other embodiments of the disclosure; and

FIGS. 10A, 10B, 10C are diagrams of the structures formed after executing each step during the process of forming the pattern of the gate electrodes in the manufacturing method according to some other embodiments of the present disclosure.

### DETAILED DESCRIPTION

In the current trend of employing low-temperature polysilicon (LTPS) and oxide thin-film transistor in the display panels, Applicant has observed the following issues.

In a conventional LTPS thin-film transistor, the active layer of a thin-film transistor has a composition of a low-temperature polysilicon, which is obtained by converting amorphous silicon into polysilicon under a relatively low temperature. The carrier mobility rate of the LTPS thin-film transistor is relatively high, and can reach around 100-500 cm²V⁻¹s⁻¹.

Yet, the LTPS thin-film transistor has a uniformity issue which is difficult to be solved at present. Therefore, if the LTPS thin-film transistor is employed in a large-size display panel, the technical obstacle is especially difficult to overcome.

In an oxide thin-film transistor, the active layer of an oxide thin-film transistor has a composition of an oxide semiconductor material. The oxide thin-film transistor can ensure a uniformity in a large-size display panel, and has a carrier mobility rate of around 10 cm²V⁻¹s⁻¹. Therefore, because of the advantages such as a high mobility rate, a good uniformity, transparency, and a simple manufacturing process associated with the oxide thin-film transistor, the oxide thin-film transistor has drawn a lot of attention currently.

Nevertheless, the characteristics of an oxide thin-film transistor can be easily influenced by lights, including the natural lights in the environment and the lights emitted by the display device itself. Usually, the threshold voltage of an oxide thin-film transistor drifts in the negative direction after the oxide thin-film transistor is exposed to the lights. This above issue is especially significant in an OLED display device, where the drift of the threshold voltage can cause a reduced display quality and a reduced instability of the display brightness.

In order to address the issues associated with the use of low-temperature polysilicon (LTPS) thin-film transistors and oxide thin-film transistors in the current display technology, the present disclosure provides a thin-film transistor and a manufacturing method thereof, an array substrate comprising the thin-film transistor, and a display device comprising the array substrate.

In the following, with reference to the drawings of various embodiments disclosed herein, the technical solutions of the embodiments of the disclosure will be described in a clear and fully understandable way. It is obvious that the described embodiments are merely a portion but not all of the embodiments of the disclosure. Based on the described embodiments of the disclosure, those ordinarily skilled in the art can obtain other embodiment(s), which come(s) within the scope sought for protection by the disclosure.

It is noted that in the thin-film transistor, its manufacturing methods thereof, an array substrate comprising the thin-film transistor, and a display device comprising the array substrate as disclosed herein, the various parameters and features, such as a thickness and a shape of each film layer in the thin-film transistor as will be shown in the follow embodiments and illustrated in the drawings, do not reflect the real and actual ratios of the thin-film transistor, the array substrate, and/or the display device, and shall thus be interpreted to only serve as illustrating purposes only and do not impose any limitation to the scope of the disclosure.

In a first aspect, the present disclosure provides a thin-film transistor.

The thin-film transistor includes a substrate, a light-shielding layer, and an active layer. The light-shielding layer is disposed over the substrate, and the active layer is disposed over the light-shielding layer. The light-shielding layer is provided with an accommodating space having a bottom wall and a side wall on an upper surface of the light-shielding layer. The active layer is arranged such that an orthographic projection of the active layer on the substrate is contained within an orthographic projection of the accommodating space of the light-shielding layer on the substrate.

It is further configured that a bottom surface of the active layer has a shorter distance to the substrate than an upper side of the side wall of the accommodating space of the light-shielding layer to the substrate. Optionally, it can be further configured that a top surface of the active layer has an equal, or shorter distance to the substrate than the upper side of the side wall of the accommodating space of the light-shielding layer to the substrate.

Herein, and elsewhere in the disclosure, the positional terms “top”, “bottom”, “upper”, “lower”, “left”, “right”, if any, are defined based on a fixed viewing angle that all structural elements/components are disposed with the reference, the “substrate”, at the very bottom, as illustrated in the various figures in the drawings of the disclosure.

It is understandable that descriptions having these positional terms shall be regarded to represent relative positions of different elements/components based on this fixed view, and with a different viewing angle, these relative positions shall remain the same. It is noted that in order to simplify the description of the disclosure, all positional relationships are depicted and illustrated with the aforementioned fixed viewing angle, i.e., that all structural elements/components are disposed with the reference, the “substrate”, at the very bottom.

Herein the bottom surface of the active layer is defined as a side of the active layer having a shortest distance to the substrate. The upper side of the side wall of the accommodating space of the light-shielding layer is defined as a side of the side wall of the accommodating space of the light-shielding layer having a largest distance to the substrate.

It is noted that similar terms or phrases, such as “bottom surface”, “top surface”, “upper side”, or “lower side”, as may have shown elsewhere in the disclosure, shall be interpreted based on the fixed viewing angle that the reference (i.e. the substrate) is at the very bottom, and based on a distance of a point/side/surface of a subject matter to the reference. For example, the phrases “bottom surface” and “lower surface” shall be interpreted as a surface of something that has a shortest distance to the reference, and the phrases “top surface” and “upper surface” shall be interpreted as a surface of something that has a largest distance to the reference.

Herein the light-shielding layer can be a gate electrode comprising a light-blocking metal. It is noted that the light-shielding layer can also be a layer of light-blocking material other than the gate electrode.

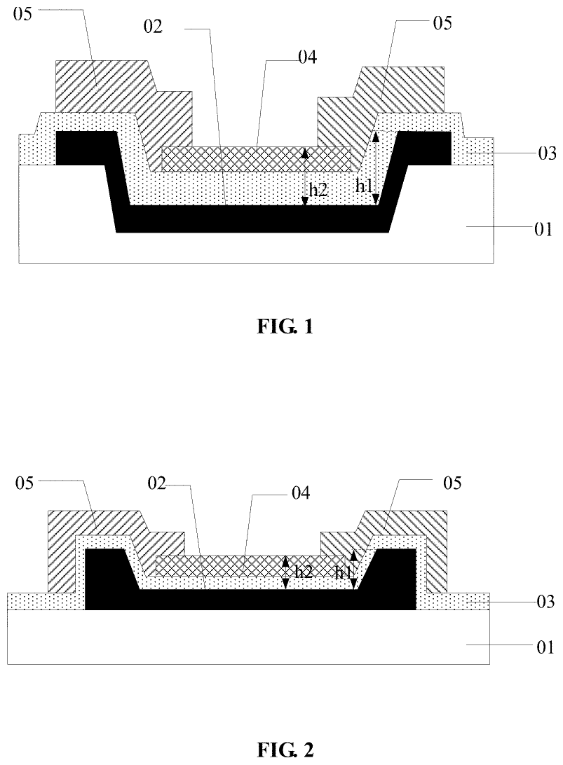

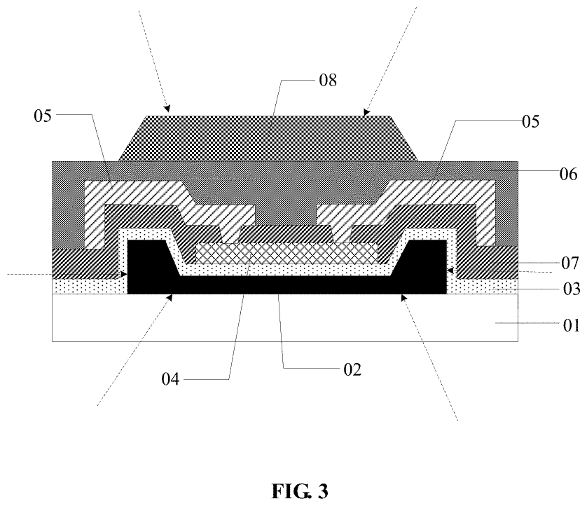

FIG. 1 and FIG. 2 illustrate a thin-film transistor with a gate electrode as the the light-shielding layer, according to two embodiments of the disclosure. As shown in FIG. 1 and FIG. 2, the thin-film transistor includes a substrate 01, a gate electrode 02, a gate insulating layer 03, an active layer 04, and source-drain electrodes 05. The gate electrode 02, the gate insulating layer 03, the active layer 04, and the source-drain electrodes 05 are successively disposed over the substrate 01.

The gate electrode 02 is provided with an accommodating space having a bottom wall and a side wall on an upper surface of the gate electrode 02. Herein the accommodating space substantially forms a well structure or a groove having a bottom wall and a side wall.

An orthographic projection of the bottom wall of the well structure (i.e. the accommodating space) in the gate electrode 02 on the substrate 01 is configured to completely cover an orthographic projection of the active layer 04 on the substrate 01.

In the well structure (i.e. the accommodating space) of the gate electrode 02, the side wall is attached with an edge of the bottom wall and further extends in a direction towards the active layer 04.

The side wall of the well structure of the gate electrode 02 is further configured to have a height that is equal to, or higher than a top surface (i.e. upper surface) of the active layer 04 (i.e. a surface of the active layer 04 opposing to, or distal to, the substrate 01). Herein the height of the side wall of the well structure of the gate electrode 02 is defined as a distance of an upper side of the side wall to the bottom wall of the gate electrode 02, and the height of the top surface of the active layer 04 is defined as a distance to the bottom wall of the gate electrode 02.

Because the whole bottom wall of the gate electrode 02 has an equal distance to the substrate 01, in other words, a distance of the upper side of the side wall of the accommodating space (i.e. the well structure, or the groove) of the gate electrode 02 to the substrate 01 is configured to be equal to, or larger than, a distance of the top surface of the active layer 04 to the substrate 01.

In the thin-film transistor as described above, the gate electrode 02 and the active layer 04 are substantially configured such that the active layer 04 is completely contained in the well structure of the gate electrode 02 (i.e. the upper side of the side well of the well structure of the gate electrode 02 is configured to have an equal or a longer distance to the substrate 01 than the top surface of the active layer 04).

By such a configuration of the thin-film transistor, the bottom wall of the well structure of the gate electrode 02 can be employed to block lights transmitted from underneath the gate electrode 02 from reaching the active layer 04, whereas the side wall of the well structure of the gate electrode 02 can be employed to block lights transmitted from a lateral side of the gate electrode 02 from reaching the active layer 04. As such, the lights that reach an active layer 04 of a thin-film transistor can be effectively reduced, which can in turn increase the stability of the thin-film transistor.

It is noted that under certain circumstances, the side wall of the well structure of the gate electrode 02 may not completely, or only partially, block lights transmitted from a lateral side of the gate electrode 02 from reaching the active layer 04 (not shown in the drawings).

For example, the side wall of the well structure of the gate electrode 02 has a height that is higher than a bottom surface (i.e. lower surface) of the active layer 04 but is lower than a top surface (i.e. upper surface) of the active layer 04. In other words, the upper surface of the side wall of the well structure of the gate electrode 02 has a larger distance to the substrate than the bottom surface (i.e. lower surface) of the active layer 04 but has a smaller distance to the substrate than the top surface (i.e. upper surface) of the active layer 04.

Under these above circumstances, although the lights that laterally reach the active layer 04 of the thin-film transistor cannot be completely blocked by the side wall of the well structure of the gate electrode 02, the side wall of the well structure of the gate electrode 02 can still reduce the lights laterally reaching the active layer 04. As a result, the stability of the thin-film transistor can still be improved.

Specifically, in the two embodiments of the thin-film transistor as shown in FIG. 1 and FIG. 2, a height h1 of the side wall of the well structure of the gate electrode 02 measured from the bottom wall of the well structure of the gate electrode 02 is equal to, or larger than, a height h2 of the top surface of the active layer 04 measured from the bottom wall of the well structure of the gate electrode 02.

According to some embodiments of the thin-film transistor, as illustrated in FIG. 1 and FIG. 2, the side wall of well structure of the gate electrode 02 is configured to completely surround the active layer 04 (i.e. the height h1 of the side wall of the well structure of the gate electrode 02 is larger than the height h2 of the top surface of the active layer 04, both measured from the bottom wall of the well structure of the gate electrode 02), and as such, all the lateral sides of the active layer are completely surrounded by the gate electrode 01, which guarantees that no light from a lateral side can reach the active layer 04 of the thin-film transistor.

According to some other embodiments of the thin-film transistor (not shown in the drawings), the side wall of well structure of the gate electrode 02 is configured to partially surround the active layer 04 (i.e. the height of the side wall of the well structure of the gate electrode 02 is smaller than the height of the top surface of the active layer 04, but larger than the height of the bottom surface of the active layer 04), and as such, the lateral sides of the active layer are partially surrounded by the gate electrode 01, which reduces light from a lateral side reaching the active layer 04 of the thin-film transistor.

The well structure of the gate electrode 02 can specifically be realized by a variety of approaches.

In the embodiment of the thin-film transistor as shown in FIG. 2, the well structure of the gate electrode 02 is realized by a groove directly arranged on a top surface of the gate electrode 02 (i.e. a surface of the gate electrode 02 that is facing, or proximate, to the active layer 04). A bottom surface and a side wall of the groove thereby respectively form the bottom wall and the side wall of the well structure of the gate electrode 02.

It is noted that in this above embodiment of the thin-film transistor, the groove can be formed directly on the gate electrode 01 through a one-time patterning process when fabricating the gate electrodes. The one-time patterning process can be based on a conventional thin-film transistor manufacturing process, and no additional patterning processes are needed.

An alternative manner for realizing the well structure of the gate electrode 02 is illustrated in the embodiment of the thin-film transistor as shown in FIG. 1. As shown in the figure, a top surface of the substrate 01 (i.e. a surface of the substrate 01 that is facing, or proximate, to the gate electrode 02) is provided with a groove, and the gate electrode 02 is disposed on the substrate 01 such that a bottom portion of the gate electrode 02 covers a bottom surface of the groove of the substrate 01, and a sidewall portion of the gate electrode 02 attaches a sidewall of the groove of the substrate 01.

It should be noted that in any of the embodiments of the thin-film transistor disclosed herein, the substrate shall be interpreted to include all the film layers that are disposed underneath the gate electrode. For example, the substrate can include just a substrate plate, and the groove is arranged just inside the substrate plate.

Alternatively, the substrate can comprise a substrate plate and one or more film layers disposed over the substrate plate, and the groove can be arranged in at least one film layer that is adjacent to the gate electrode 02. There are no limitations herein.

In the disclosure, the process of forming a groove over the substrate 01 is relatively complicated, and in some preferred embodiments of the thin-film transistor, the groove is arranged over the gate electrode 02.

If the thin-film transistor is an oxide thin-film transistor (i.e. the active layer has a composition of an oxide semiconductor material), the active layer is relatively sensitive to lights, and therefore, a thin-film transistor having a gate electrode 02 having a well structure, as described above in the embodiments of the disclosure and illustrated in FIG. 1 and FIG. 2, are particularly suitable for an oxide thin-film transistor.

As such, according to some preferred embodiments of the disclosure, the thin-film transistor is an oxide thin-film transistor, and the active layer has a composition of an oxide semiconductor material.

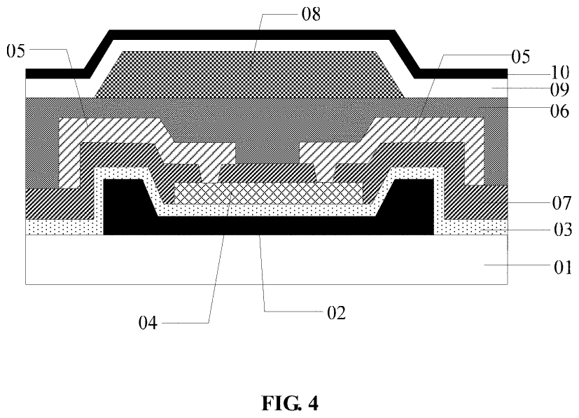

The thin-film transistor can further include other film layers. According to some embodiment of the present disclosure as illustrated in FIG. 3, the thin-film transistor further includes a passivation layer 06, which is disposed over the source-drain electrodes 05. The passivation layer 06 is configured to protect the source-drain electrodes 05 and the active layer 04.

Further as shown in FIG. 3, in order to prevent damages to the active layer 04 when forming the source-drain electrodes 05, the thin-film transistor further includes an etch stop layer 07, which is disposed between the active layer 04 and the source-drain electrodes 05. In the thin-film transistor disclosed herein, the source-drain electrodes 05 are electrically coupled or connected to the active layer 04 through at least one via in the etch stop layer 07.

Furthermore, in the thin-film transistor disclosed herein, in order to prevent lights from above the active layer 04 from reaching onto the active layer 04, as shown by the two downward arrows in FIG. 3, the thin-film transistor can further include a light filtering layer 08, which is disposed over the passivation layer 06. It is configured such that an orthographic projection of the light filtering layer 08 on the substrate 01 completely covers an orthographic projection of the active layer 04 on the substrate 01.

In the thin-film transistor according to some preferred embodiments of the present disclosure, the light filtering layer 08 is a red color filter layer (i.e. the light filtering layer 08 can absorb lights of all other colors except a red light when the lights are passing through the light filtering layer 08).

This is because the active layer 04 is normally more sensitive to short-wavelength light such as a green light and a blue light in visible lights, and an influence of a long-wavelength light, such as a red light, is not so big. As such, as long as the light filtering layer 08 can absorb the short-wavelength lights, the influence of the light from above the active layer 04 to the active layer 04 can be greatly reduced.

Additionally, if the light filtering layer 08 is configured as red colored (i.e. the light filtering layer 08 is a red color filter layer), the light filtering layer 08 can be arranged to be in a substantially same layer as a red color film for each pixel region in the display panel. Consequently, such a configuration further allows the light filtering layer 08 to be fabricated during a same patterning process as the red color film for each pixel region. As such, the patterning process for the display panel can be simplified, and the manufacturing cost can be saved.

According to some other embodiments of the disclosure, the light filtering layer 08 can have a composition of a light-blocking material, which can completely block all lights from passing therethrough. However, if the thin-film transistor comprises a light filtering layer 08 having a composition of a light-blocking material, one additional patterning process specifically for the light filtering layer 08 is needed during fabrication of the thin-film transistor.

In a second aspect, the present disclosure further provides an array substrate.

The array substrate includes a thin-film transistor according to any one of the embodiments of the present disclosure as described above. The description of technical details of the array substrate can be referenced to the description of the thin-film transistor that foregoes, and is skipped herein.

In the array substrate disclosed herein, because of the presence of accommodating space of the light-shielding layer (such as the well structure of the gate electrode according to some embodiments) having a bottom surface and a side wall, which are configured to partially or completely surround the active layer (i.e. an orthographic projection of the bottom surface on the substrate completely covers an orthographic projection of the active layer on the substrate, and an upper side of the side wall of the well structure has a larger distance to the substrate than a bottom surface of the active layer), lights from an underneath and from all lateral sides of the thin-film transistors that can otherwise reach the active layer can be partially or completely blocked.

As such, the lights that reach the active layer of the thin-film transistor in the array substrate can be effectively reduced, which can in turn increase a stability of the thin-film transistor and of the array substrate.

Optionally, in the array substrate disclosed herein, the thin-film transistor may further include a light filtering layer, which can have a composition of a light-blocking material according to some embodiments or can comprise a red color filter layer according to some other embodiments, which can block lights from above the active layer from reaching onto the active layer. As such, the lights that reach the active layer of the thin-film transistor in the array substrate can be further reduced, further increasing the stability of the thin-film transistor and of the array substrate.

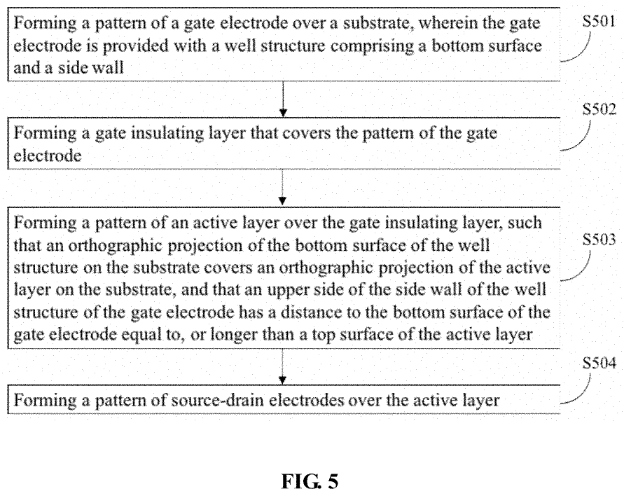

If the array substrate is applied in an OLED display panel, the array substrate, according to some embodiments of the present disclosure as illustrated in FIG. 4, can further include a light-emitting layer 09 and an anode layer 10, which are disposed successively over the light filtering layer 08. As such, lights emitted from the light-emitting layer 09 that are reflected by the anode layer 10 can be effectively blocked or filtered by the light filtering layer 08.

In a third aspect, the present disclosure further provides a display device.

The display device includes an array substrate according to any one of the embodiments as described above. The display device can be a liquid crystal display device, or can be an OLED display device.

It is noted that other parts of the display device are known to those of ordinary skills in the art, description of these parts of the display device can thus be skipped herein.

Specifically, the display device may be any electronic component or electronic product having a display functionality, such as a display monitor, a mobile phone, a tablet, a television, a notebook, a digital frame, a digital camera, or a navigating instrument (e.g. GPS).

In specific implementation, it is noted that the influence of lights inside a liquid crystal display (LCD) device on the thin-film transistors disposed therein does not have a significant effect on the display quality of the LCD device.

As for an OLED display device, however, because it is driven by electric currents, the influence of lights inside an OLED display device on the thin-film transistors disposed therein has an especially significant effect on the display quality thereof. Therefore, in a preferred embodiment, the display device is an OLED display device.

In a fourth aspect, the present disclosure further provides a method for manufacturing the thin-film transistor according to any one of the embodiments as described above.

The method comprises the following steps:

providing a substrate;

forming a light-shielding layer over the substrate such that an accommodating space having a bottom wall and a side wall is formed on an upper surface thereof and

forming an active layer over the light-shielding layer such that an orthographic projection thereof on the substrate is within an orthographic projection of the accommodating space of the light-shielding layer on the substrate, and a bottom surface thereof has a shorter distance to the substrate than an upper side of the side wall of the accommodating space of the light-shielding layer to the substrate.

According to some embodiments of the method, in the forming an active layer over the light-shielding layer, the active layer is further arranged such that a top surface thereof has an equal, or shorter distance to the substrate than the upper side of the side wall of the accommodating space of the light-shielding layer to the substrate.

The light-shielding layer as described above can be a gate electrode, and as such, the step of forming a light-shielding layer over the substrate comprises:

forming a gate electrode over the substrate such that a first groove is formed on an upper surface thereof to substantially form the accommodating space of the light-shielding layer.

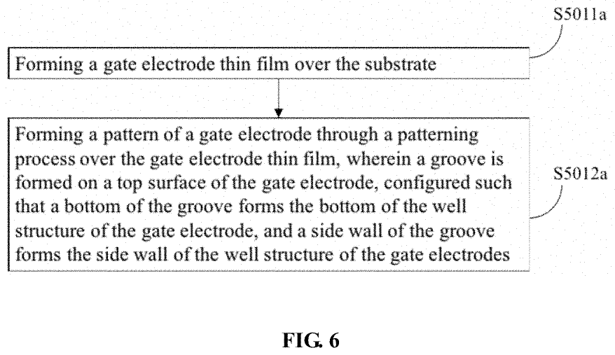

FIG. 5 illustrates a flow chart illustrating a manufacturing method of a thin-film transistor according to some embodiments of the present disclosure. As shown in FIG. 5, the method comprises the following steps:

S501: forming a pattern of a gate electrode over a substrate, wherein the gate electrode is provided with a well-structure comprising a bottom surface and a side wall;

S502: forming a gate insulating layer that covers the pattern of the gate electrode;

S503: forming a pattern of an active layer over the gate insulating layer, such that an orthographic projection of the bottom surface of the well structure of the gate electrode on the substrate covers an orthographic projection of the active layer on the substrate, and that an upper side of the side wall of the well structure of the gate electrode has a distance to the bottom surface of the gate electrode that is equal to, or longer than a top surface of the active layer; and

S504: forming a pattern of source-drain electrodes over the active layer.

In the thin-film transistor manufactured by the method as described above, the bottom surface of the well structure of the gate electrode can be employed to block lights transmitted from underneath the gate electrode from reaching the active layer 04, and the side wall of the well structure of the gate electrode can be employed to block lights transmitted from a lateral side of the gate electrode from reaching the active layer.

As such, the lights that reach the active layer can be effectively reduced, which can in turn increase the stability of the thin-film transistor.

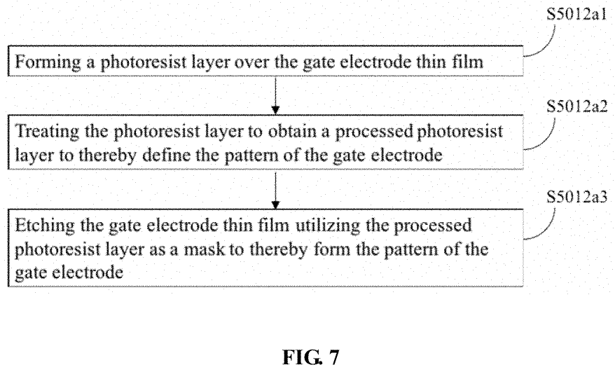

According to some embodiments of the present disclosure as illustrated in FIG. 6, the step S501 (i.e. the forming a pattern of a gate electrode over a substrate) comprises the following sub-steps:

S5011a: forming a gate electrode thin film 11 over the substrate 01; and

S5012a: forming a pattern of a gate electrode through a patterning process over the gate electrode thin film 11, wherein a groove is formed on a top surface of the gate electrode, configured such that a bottom surface of the groove forms the bottom surface of the well structure of the gate electrode, and a side wall of the groove forms the side wall of the well structure of the gate electrode.

In specific implementation, in order to reduce the total number of patterning, in some embodiments of the methods, the patterning process over the gate electrode thin film to thereby form the pattern of the gate electrode can be conducted utilizing a mask plate.

As such, the step S5012a (i.e. the step of forming a pattern of a gate electrode through a patterning process over the gate electrode thin film) can specifically include the following sub-steps:

S5012a1: forming a photoresist layer 12 over the gate electrode thin film 11;

S5012a2: treating the photoresist layer 12 to obtain a processed photoresist layer to thereby define the pattern of the gate electrode; and

S5012a3: etching the gate electrode thin film 11 utilizing the processed photoresist layer 12 as a mask to thereby form the pattern of the gate electrode.

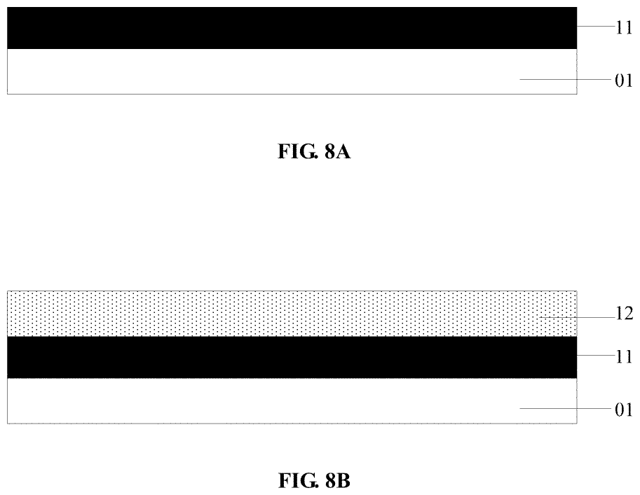

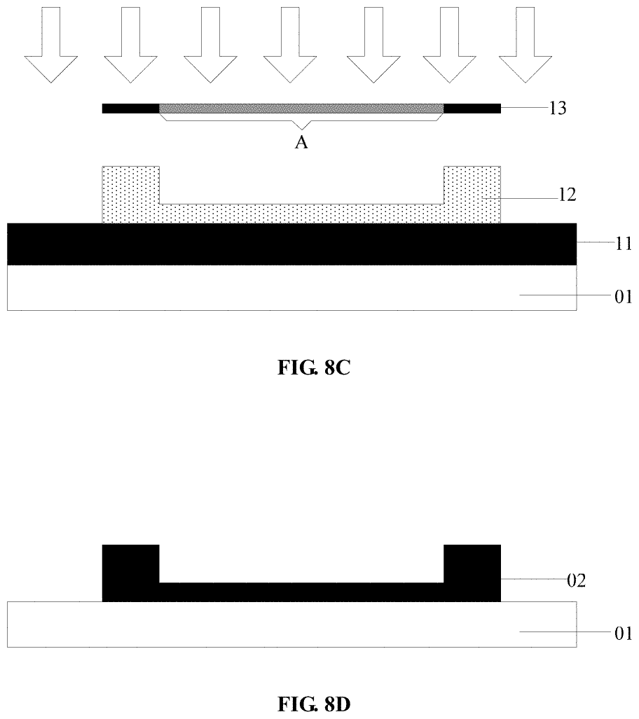

Herein the various sub-steps (S5012a1, S5012a2, and S5012a3) for performing the step S5012a is illustrated in FIG. 7, and the diagrams of structures respectively formed by the step S5011a (i.e. the forming a gate electrode thin film over the substrate), S5012a1, S5012a2, and S5012a3 are illustrated FIG. 8A, FIG. 8B, FIG. 8C, and FIG. 8D, respectively.

It is noted that the step S5012a2 (i.e. the treating the photoresist layer to obtain a processed photoresist layer) can comprise:

using a mask plate to treat the photoresist layer, wherein a translucent region is arranged in the mask plate to correspond to a region of the groove.

Herein the mask plate can be a half-tone mask or a gray-tone mask, and as shown in FIG. 6C, the translucent region A substantially corresponds to the region of the groove to be formed on the gate electrode.

In specific implementation, the depth of the groove (i.e. the distance between the upper side of the side wall of the groove to the bottom surface of the groove) can be adjusted by adjusting a transmittance of the translucent region in the mask plate (the half-tone mask plate or the gray-tone mask plate).

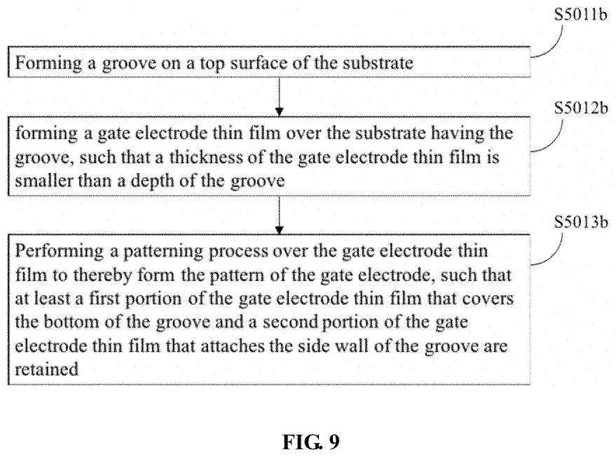

Alternatively, according to some other embodiments of the present disclosure, as illustrated in FIG. 9, the step S501 (i.e. the step of forming the pattern of the gate electrode over the substrate) specifically comprises the following sub-steps:

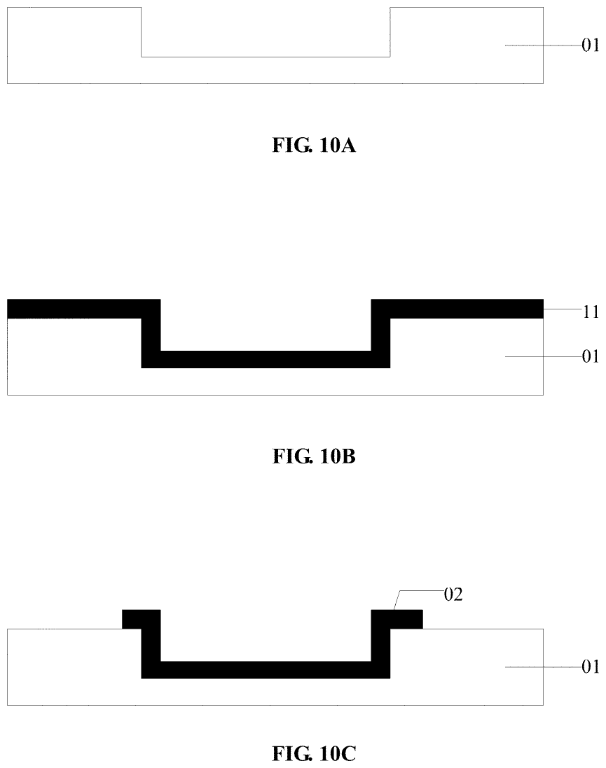

S5011b: forming a groove on a top surface of the substrate 01, as shown in FIG. 10A;

S5012b: forming a gate electrode thin film 11 over the substrate 01 having the groove, such that a thickness of the gate electrode thin film 11 is smaller than a depth of the groove, as shown in FIG. 10B;

S5013b: performing a patterning process over the gate electrode thin film 11 to thereby form the pattern of the gate electrode 02, such that at least a first portion of the gate electrode thin film 11 that covers the bottom surface of the groove and a second portion of the gate electrode thin film 11 that attaches the side wall of the groove are retained, as shown in FIG. 10C.

It should be noted that in the aforementioned embodiments of the method, the patterning process may only comprise a photolithographic process, or may comprise a photolithographic process and an etching process, or may further comprise other processes that can be employed to form preset patterns such as printing or ink-jet printing.

Herein the photolithographic process is referred to as the process to form patterns utilizing photoresists, mask plates, exposure machines, etc., and may include sub-processes such as film formation, exposure, and development, etc. In specific implementation, the specific processes or sub-processes can be selected based on specific structures that are formed in the present disclosure.

In any of the embodiments of the thin-film transistor, the manufacturing method of the thin-film transistor, the array substrate comprising the thin-film transistor, and the display device comprising the array substrate as described above, the gate electrode in the thin-film transistor is provided with a well structure comprising a bottom surface and a side wall, and the active layer of the thin-film transistor is configured to be completely contained in the well structure of the gate electrode of the thin-film transistor.

Specifically, an orthographic projection of the bottom surface of the well structure of the gate electrode on the substrate completely covers an orthographic projection of the active layer on the substrate, and an upper side of the side wall of the well structure of the gate electrode is configured to have an equal or a longer distance to the bottom surface of the gate electrode than a top surface of the active layer.

Such a configuration allows the bottom surface of the well structure of the gate electrode to be able to block lights from an underneath side of the gate electrode from reaching the active layer, and further allows the side wall of the well structure of the gate electrode to be able to block lights from a lateral side of the gate electrode from reaching the active layer.

Optionally, in the thin-film transistor, a light filtering layer can be further arranged over the active layer, which can have a composition of a light-blocking material according to some embodiments or can comprise a red color filter layer according to some other embodiments. The light filtering layer can block lights from above the active layer from reaching onto the active layer. As such, the lights that reach the active layer of the thin-film transistor can be further reduced, further increasing the stability of the thin-film transistor and of the array substrate.

As such, the lights that reach the active layer of thin-film transistors in the array substrate can be effectively reduced, which can in turn increase the stability of the thin-film transistor.

Although specific embodiments have been described above in detail, the description is merely for purposes of illustration. It should be appreciated, therefore, that many aspects described above are not intended as required or essential elements unless explicitly stated otherwise.

Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A thin-film transistor, comprising:
a substrate;
a light-shielding layer over the substrate; and
an active layer over the light-shielding layer;
wherein:
the light-shielding layer is provided with an accommodating space having a bottom wall and a side wall on an upper surface thereof; and
the active layer is arranged such that:
an orthographic projection thereof on the substrate is within an orthographic projection of the accommodating space of the light-shielding layer on the substrate; and
a bottom surface thereof has a shorter distance to the substrate than an upper side of the side wall of the accommodating space of the light-shielding layer to the substrate.

2. The thin-film transistor of claim 1, wherein the active layer is further arranged such that a top surface thereof has an equal, or shorter distance to the substrate than the upper side of the side wall of the accommodating space of the light-shielding layer to the substrate.

3. The thin-film transistor of claim 1, wherein the light-shielding layer comprises a gate electrode, wherein:
the gate electrode is provided with a first groove on an upper surface thereof; and
the first groove substantially forms the accommodating space of the light-shielding layer.

4. The thin-film transistor of claim 3, wherein the substrate is provided with a second groove on an upper surface thereof, configured such that the second groove is conformal with the first groove of the gate electrode.

5. The thin-film transistor of claim 3, further comprising at least one intermediate layer between the substrate and the gate electrode, wherein:
each of the at least one intermediate layer is provided with a third groove on an upper surface thereof, configured such that the third groove is conformal with the first groove of the gate electrode.

6. The thin-film transistor of claim 1, wherein the active layer has a composition of an oxide semiconductor material.

7. An array substrate, comprising a thin-film transistor according to claim 1.

8. The array substrate according to claim 7, further comprising a light filtering layer over the active layer of the thin-film transistor, wherein:
an orthographic projection of the light filtering layer on the substrate covers an orthographic projection of the active layer on the substrate; and
the light filtering layer is configured to reduce or block lights from above the active layer to reach the active layer.

9. The array substrate according to claim 8, wherein the light filtering layer in the thin-film transistor has a composition of a light-blocking material configured to substantially block the lights from above the active layer to reach the active layer.

10. The array substrate according to claim 8, wherein the light filtering layer in the thin-film transistor has a composition configured to absorb a relatively short-wavelength light yet still allow a relatively long-wavelength light to pass therethrough.

11. The array substrate according to claim 10, wherein the light filtering layer in the thin-film transistor is a red color filter layer.

12. The array substrate according to claim 7, further comprising a light-emitting assembly, selected from OLED, QLED, or microLED.

13. The array substrate according to claim 12, wherein the light-emitting assembly is an OLED light-emitting assembly, comprising:
a light-emitting layer over the light filtering layer; and
a cathode layer over the light-emitting layer.

14. The array substrate according to claim 13, wherein the cathode layer is configured to be reflective on a surface thereof facing the light-emitting layer.

15. A method for manufacturing a thin-film transistor, comprising:
providing a substrate;
forming a light-shielding layer over the substrate such that an accommodating space having a bottom wall and a side wall is formed on an upper surface thereof; and
forming an active layer over the light-shielding layer such that an orthographic projection thereof on the substrate is within an orthographic projection of the accommodating space of the light-shielding layer on the substrate, and a bottom surface thereof has a shorter distance to the substrate than an upper side of the side wall of the accommodating space of the light-shielding layer to the substrate.

16. (canceled)

17. The method of claim 15, wherein the forming a light-shielding layer over the substrate comprises:
forming a gate electrode over the substrate such that a first groove is formed on an upper surface thereof to substantially form the accommodating space of the light-shielding layer.

18. The method of claim 17, wherein the forming a gate electrode over the substrate comprises:
forming a gate electrode thin film over the substrate;
forming a photoresist layer over the gate electrode thin film;
treating the photoresist layer to obtain a processed photoresist layer to thereby define the pattern of the gate electrode; and
etching the gate electrode thin film utilizing the processed photoresist layer as a mask to thereby form the gate electrode.

19. The method of claim 18, wherein the treating the photoresist layer to obtain a processed photoresist layer comprises:
using a mask plate to treat the photoresist layer, wherein a translucent region is arranged in the mask plate to correspond to a region of the groove.

20. The method of claim 19, wherein in the using a mask plate to treat the photoresist layer, the mask plate is a half-tone mask plate or a gray-tone mask plate.

21. The method of claim 17, wherein:
the providing a substrate comprises:
providing the substrate; and
forming a second groove on a top surface of the substrate;
and
the forming a gate electrode over the substrate comprises:
forming a gate electrode thin film having a thickness thereof smaller than a depth of the second groove; and
performing a patterning process over the gate electrode thin film to thereby form the gate electrode.
